(19) United States
(12) Patent Application Publication
(10) Pub. No.: US 2002/0125483 A1
(43) Pub. Date: Sep. 12, 2002

(54) Insulated base semiconductor component

(76) Inventor: Thorsten Meyer, Munchen (DE)

Correspondence Address: LERNER AND GREENBERG, P.A., PATENT ATTORNEYS AND ATTORNEYS AT LAW, POST OFFICE BOX 2480, Hollywood, FL, 33022-2480, US

(21) Appl. No.: 10/093,709

(22) Filed: Mar. 8, 2002

(30) Foreign Application Priority Data
Mar. 8, 2001 (DE) 101 11 152.5

(51) Int. Cl. H01L 31/0312

(52) U.S. Cl. 257/77

(57) ABSTRACT

The semiconductor component has a first terminal zone of a first conductivity type and a drift zone of the first conductivity type adjoining the first terminal zone. Further, the component has a second terminal zone of the first conductivity type and a third terminal zone of the first conductivity type. A blocking zone is formed between the drift zone and the second terminal zone and between the drift zone and the third terminal zone. A contact short-circuits the second terminal zone and the blocking zone. A control electrode is formed to be insulated from the drift zone, the blocking zone, and the second terminal zone. An electrical resistor is formed between the contact and the third terminal zone.

### BACKGROUND OF THE INVENTION

### Field of the Invention

The invention lies in the semiconductor technology field. More specifically, the invention pertains to a semiconductor component with a first terminal zone of a first conductivity type and a drift zone of the first conductivity type adjoining the first terminal zone; a second terminal zone of the first conductivity type; a third terminal zone of the first conductivity type; a blocking zone formed between the drift zone and the second terminal zone and the drift zone and the third terminal zone; a contact, which short-circuits the second terminal zone and the blocking zone; and a control electrode, which is formed so as to be insulated from the drift zone, the blocking zone, and the second terminal zone. Such a semiconductor component, known as an IBT (Insulated Base Transistor), is disclosed for example in U.S. Pat. No. 5,969,378; in De Souza, Spulber, Narayanan: “A Novel ‘Cool’ Insulated Base Transistor”, ISPSD 2000, Catalog Number 00CH37049C; or in Parpia, Mena, Salama: “A Novel CMOS-Compatible High-Voltage Transistor Structure”, IEEE Transactions on Electron Devices, Vol. ED-33, No. 12, 1986, page 1949, FIG. 2.

The component combines properties of a MOS transistor and of a bipolar transistor, the MOS transistor serving for driving the base of the bipolar transistor. In order to realize an n-channel transistor and an npn bipolar transistor, in the case of the prior art component according to De Souza, Spulber, Narayanan, a p-doped well is formed in an n-doped semiconductor body. The p-doped well forms the base of the bipolar transistor and the body zone of the MOS transistor. A heavily n-doped zone is formed in the semiconductor body in a manner spaced apart from the p-doped well, the zone simultaneously forming the drain terminal of the MOS transistor and the collector terminal of the bipolar transistor. Two n-doped zones are formed spaced apart from one another in the p-doped well, one of which zones is short-circuited to the p-doped well by means of a contact and forms the source zone of the MOS transistor. A gate electrode is arranged in a manner insulated from the semiconductor body in such a way that, in the p-doped well, a conductive channel forms between the source zone and the drift zone when a voltage is applied between the gate electrode and the source zone. The other of the n-doped zones formed in the p-doped well forms the emitter of the bipolar transistor. If, in the case of the prior art component, a voltage is applied between the gate electrode and the source zone, then electrons pass via a conductive channel in the body zone into the source zone. There results from this electron current, via the contact connected to the source zone, a hole current into the body zone or the base of the bipolar transistor, as a result of which the bipolar transistor is turned on. In the case of the prior art component, the bipolar transistor is driven via the MOS transistor, as a result of which, in the component, the good current conduction properties, or the low on resistance of a bipolar transistor, is combined with the low-power driving of a MOS transistor.

In order to turn off the semiconductor component, or the bipolar transistor, the holes in the base must recombine with free electrons, which leads to a comparatively long delay time during turn-off. In order to shorten this delay time, De Souza, Spulber, Narayanan, supra; or Parpia, Mena, Salama, supra, page 1951, FIG. 7 discloses connecting a resistor between the emitter and the base of the bipolar transistor. In order to make contact with the base, in the case of the known components, a separate base terminal is formed by providing a heavily p-doped zone in the base in a manner spaced apart from the emitter zone. When the gate terminal of the MOS transistor is driven, a hole current is generated in the base in the manner described, which flows away via the additional base contact. If this current becomes so large that the voltage dropped across the additional resistor reaches the threshold voltage of the bipolar transistor, then the bipolar transistor starts to conduct.

This separate base terminal increases the space requirement in the realization of the component. Secondly, a voltage drop which leads to inhomogeneous potential conditions in the semiconductor body arises between the separate base contact and the emitter zone. This leads to non-uniform current densities when the component is in the on state.

### SUMMARY OF THE INVENTION

It is accordingly an object of the invention to provide a semiconductor component with insulated base, which overcomes the above-mentioned disadvantages of the heretofore-known devices and methods of this general type and which provides for a semiconductor component that can be realized in a space-saving manner and which, in particular, does not have the disadvantages mentioned above.

With the foregoing and other objects in view there is provided, in accordance with the invention, a semiconductor component, comprising:

a first terminal zone of a first conductivity type and a drift zone of the first conductivity type adjoining the first terminal zone;

a second terminal zone of the first conductivity type;

a third terminal zone of the first conductivity type;

a blocking zone formed between the drift zone and the second terminal zone and between the drift zone and the third terminal zone;

a contact short-circuiting the second terminal zone and the blocking zone;

a control electrode formed to be insulated from the drift zone, the blocking zone, and the second terminal zone; and

an electrical resistor formed between the contact and the third terminal zone.

The semiconductor component according to the invention has a first terminal zone of a first conductivity type, a drift zone of the first conductivity type adjoining the first terminal zone, a second terminal zone of the first conductivity type, a third terminal zone of the first conductivity type and a blocking zone of a second conductivity type, which is formed between the drift zone and the second terminal zone and the drift zone and the third terminal zone. In this case, the second terminal zone and the blocking zone are short-circuited by means of a contact, in particular made of metal. Furthermore, a control electrode is formed in a manner insulated from the drift zone, the blocking zone and the second terminal zone. The semiconductor component according to the invention realizes an arrangement having a MOS transistor and a bipolar transistor, the base of the bipolar transistor being driven by the MOS transistor, or a so-called IBT. In this case, the first terminal zone forms the drain zone of the MOS transistor and the collector of the bipolar transistor. The blocking zone forms the body zone of the MOS transistor and the base of the bipolar transistor. The second terminal zone, which is short-circuited to the blocking zone, or the body zone, forms the source zone of the MOS transistor and the third terminal zone, which is formed in a manner spaced apart from the second terminal zone, forms the emitter of the bipolar transistor. According to the invention, a resistor is connected between the emitter and the contact which short-circuits the first terminal zone and the blocking zone. This resistor is preferably formed as an external resistor, that is to say the resistor is not part of a semiconductor body wherein the terminal zones and the blocking zone are formed. The resistor is preferably composed of a semiconductor material and is arranged in an insulated manner on the semiconductor body.

In the case of the semiconductor component according to the invention, wherein the resistor is connected to the emitter and the contact between source zone and body zone or base, there is no need for a separate contact in order to connect the resistor to the base of the bipolar transistor, which reduces the space requirement in the realization of the component. Moreover, dispensing with an external base terminal results in a more homogeneous distribution of the current density in the blocking zone or base.

In accordance with one embodiment of the invention, the blocking zone is formed like a well in the drift zone, and that the second and third terminal zones are formed such that they are spaced apart from one another in the blocking zone. The blocking zone and the first, second and third terminal zones are formed in a semiconductor body, in a first embodiment the first terminal zone being arranged in a manner spaced apart from the blocking zone or the second and third terminal zones in the lateral direction of the semiconductor body, in order to form a lateral component wherein the terminals are accessible from a side of the semiconductor body.

In accordance with a further embodiment of the invention, the first terminal zone is arranged in a manner spaced apart from the blocking zone or the second and third terminal zones in the vertical direction of the semiconductor body, the second terminal zone, which forms the emitter of the bipolar transistor, and the first terminal zone, which forms the collector of the bipolar transistor, being accessible at opposite sides of the semiconductor body.

If, in bipolar transistors, the maximum reverse voltage thereof is reached and the transistors enter into breakdown, then a so-called “snapback effect” occurs, which is manifested in a reduction of the breakdown voltage after a voltage breakdown on account of majority charge carriers accumulating in an avalanche-like manner in the base. This is particularly critical because the breakdown voltage is reduced to different extents or at different points in time in different regions of the base-collector diode of the bipolar transistor, the diode being responsible for the breakdown, with the result that some regions of the base-collector diode are still in the off state, while others are already in the on state due to the breakdown. This can lead to overloading of the conductive regions and to destruction of the component.

In order to avoid this problem, in a further embodiment of the invention, a breakdown structure integrated into the semiconductor body is provided, which is dimensioned in such a way that when a voltage is applied between the collector terminal and the emitter terminal of the bipolar transistor, it breaks down or conducts before the breakdown voltage of the bipolar transistor is reached. The breakdown structure has two terminals, of which one is connected to the emitter terminal of the bipolar transistor and the other is connected to the collector terminal of the bipolar transistor. The breakdown structure preferably has a doped zone of the second conductivity type formed in the drift zone, the breakdown voltage of the breakdown structure being determined by the doping of the drift zone and the distance between the doped zone of the second conductivity type and the first terminal zone.

A further embodiment of the invention provides for a transistor to be connected between the third terminal zone, which forms the emitter of the bipolar transistor, and the base zone or contact common to the body zone of the blocking zone and the source zone. In this embodiment, the transistor functions as a controllable resistor and serves for setting the switching properties of the component. If the transistor is fully turned on, then the emitter terminal of the bipolar transistor and the base thereof are short-circuited and the semiconductor component according to the invention then functions in the manner of a MOS transistor. If the transistor turns off, or is not fully turned on, which results in a non-negligible resistance between the emitter of the bipolar transistor and the base thereof, then the semiconductor component according to the invention functions as an IBT wherein a bipolar transistor is driven by a MOS transistor.

Other features which are considered as characteristic for the invention are set forth in the appended claims.

Although the invention is illustrated and described herein as embodied in an insulated base semiconductor component, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a side view of a section through a semiconductor component according to the invention in accordance with one embodiment of the invention;

FIG. 2 is a section taken along the sectional area shows a component according to the invention in cross section along a sectional area A-A in FIG. 1 in accordance with a first embodiment;

FIG. 3 shows a component according to the invention in cross section along a sectional area A-A in FIG. 1 in accordance with a second embodiment;

FIG. 4 shows an electrical equivalent circuit diagram of the semiconductor component in accordance with FIG. 1;

FIG. 5 is a side view of a section through a semiconductor component according to the invention in accordance with a second embodiment of the invention;

FIG. 6 is a side view of a section through a semiconductor component according to the invention in accordance with a third embodiment of the invention;

FIG. 7 is a side view of a section through a semiconductor component according to the invention in accordance with a fourth embodiment of the invention.

### DESCRIPTION OF THE PREFERRED EMBODIMENTS

The present invention will now be explained below with reference to an n-conducting IBT, that is to say a component wherein an npn bipolar transistor and an n-channel MOS transistor are combined with one another. Semiconductor zones of the first conductivity type hereinafter denote n-doped zones and semiconductor zones of the second conductivity type hereinafter denote p-doped zones. It goes without saying that the invention is not restricted to n-conducting components, but can likewise be applied to p-conducting components, wherein case the n-doped regions hereinafter then have to be replaced by p-doped regions and the p-doped regions hereinafter then have to be replaced by n-doped regions.

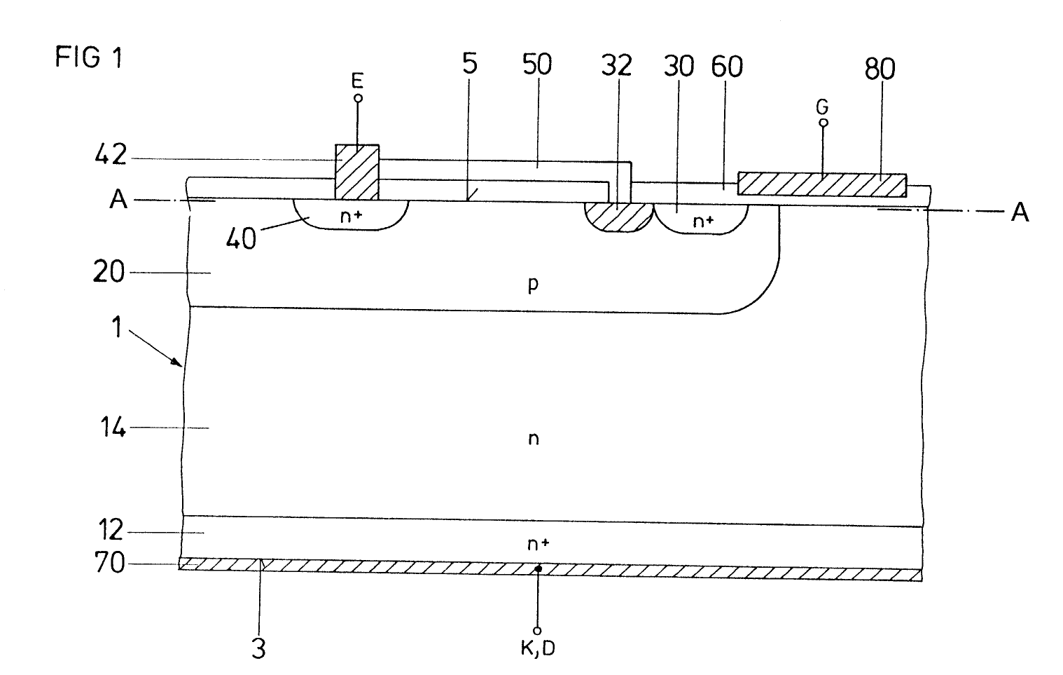

Referring now to the figures of the drawing in detail and first, particularly, to FIG. 1 thereof, there is shown a first exemplary embodiment of a semiconductor component according to the invention in cross section. The component has an n-doped semiconductor body 1 having, in the region of a rear side 3, a heavily n-doped first terminal zone 12, with which contact is made by means of a contact layer 70, in particular a metal. The remaining n-doped region of the semiconductor body forms a drift zone 14. Proceeding from a front side 5, a p-doped well 20 is formed in the semiconductor body 1, which well forms a blocking zone, a heavily n-doped second terminal zone 30 and a heavily n-doped third terminal zone 40 being formed spaced apart from one another in the p-doped well.

A region which is formed between the first terminal zone 12 and the blocking zone 20 and extends alongside the blocking zone 20 as far as the front side 5 of the semiconductor body 1 forms an n-doped drift zone of the semiconductor component.

A control electrode 80 is formed so as to be insulated from the semiconductor body 1. The control electrode 80 extends in the lateral direction of the semiconductor body 1 from the second terminal zone 30 across the blocking zone 20 as far as a region of the drift zone 14 which reaches as far as the front side 5 of the semiconductor body 1. The control electrode 80 is insulated from the semiconductor body 1 by an insulation layer 60 applied to the front side 5. The second terminal zone 30 is short-circuited to the blocking zone 20 by means of a contact 32. The contact 32 is preferably composed of a metal, for example aluminum.

The first terminal zone 12, the drift zone 14, the blocking zone 20, the second terminal zone 30, and the control electrode 80 form a MOS transistor and the first terminal zone 12, the drift zone 14, the blocking zone 20 and the third terminal zone 40 form a bipolar transistor, as is illustrated below.

The first heavily n-doped terminal zone 12 simultaneously forms the drain zone of the MOS transistor and the collector of the bipolar transistor. The more weakly n-doped drift zone 14 forms the drift zone both of the MOS transistor and of the bipolar transistor. The p-doped zone 20 forms the body zone of the MOS transistor, the source zone thereof being formed by the heavily n-doped second terminal zone 30. The control electrode 80 forms the gate electrode of the MOS transistor for forming a conductive channel between the source zone 30 and the drift zone 14 in the body zone 20 when a voltage is applied between the gate electrode 80 and the source zone 30. The p-doped zone 20 also forms the base of the bipolar transistor, whose emitter is formed by the heavily n-doped zone 40, an emitter contact 42 being provided on the front side 5 of the semiconductor body 1 in order to make contact with the emitter.

Contact can be made jointly with the source zone 30 of the MOS transistor and the base zone 20 of the bipolar transistor via the contact 32, which is designated as source-base contact below. A resistor 50 is formed between the source-base contact 32, which short-circuits the source zone 30 and the base, and the emitter contact 42, which resistor is formed as an external resistor, i.e. is not realized in the semiconductor body 1, in the exemplary embodiment illustrated in FIG. 1. In the exemplary embodiment, the external resistor 50 comprises a semiconductor layer 50 insulated from the semiconductor body 14 by part of the insulation layer 60, the insulation layer 60 having a cutout at which the semiconductor layer 50 makes contact with the source-base contact 32.

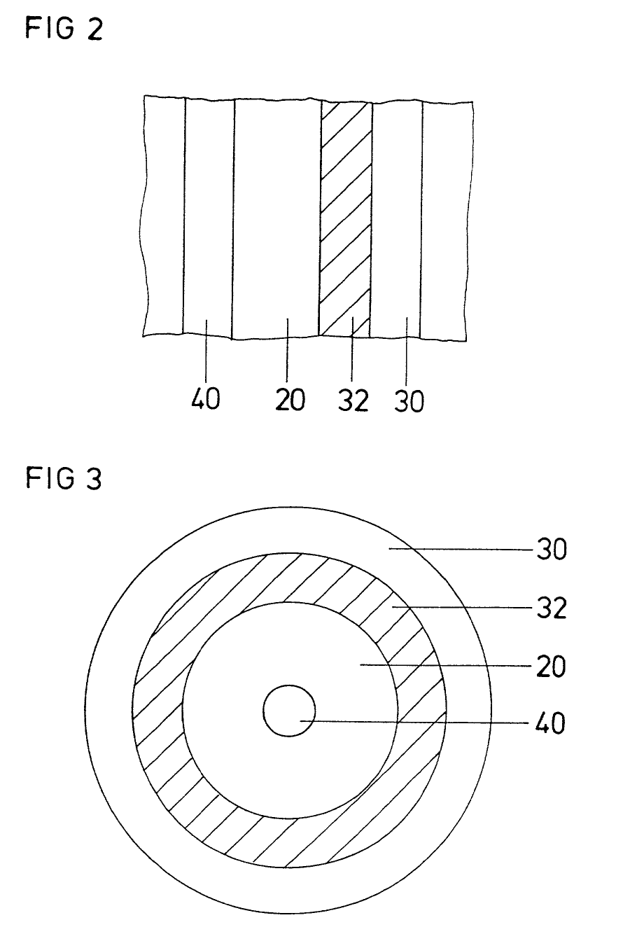

FIG. 1 shows a detail of the semiconductor component according to the invention in cross section. In this case, the emitter zone 40, the source zone 30, the gate electrode 80 and the source-base contact 32 may run in an elongate manner perpendicularly to the plane of the drawing, as illustrated by the cross-sectional illustration along the line A-A in FIG. 2. In a further embodiment, the source-base contact 32, the source zone 30 and the gate electrode 80, and also the p-doped well 20, are arranged centrosymmetrically around the emitter zone 40, as illustrated by the sectional illustration in FIG. 3.

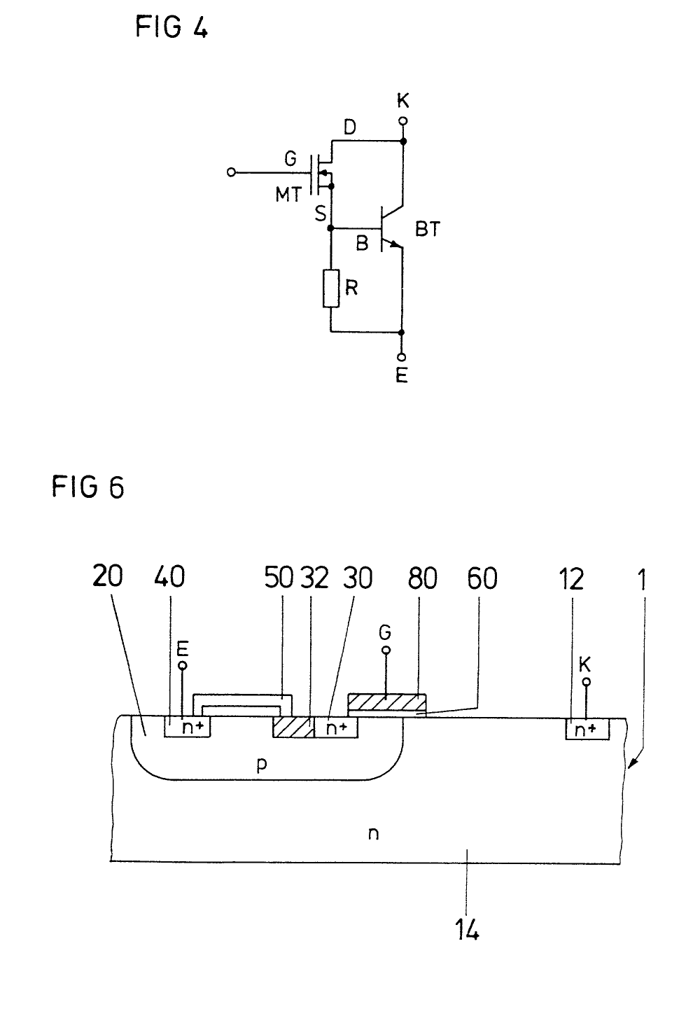

FIG. 4 shows the electrical equivalent circuit diagram of the semiconductor component according to the invention in accordance with FIG. 1. Accordingly, the semiconductor component according to the invention has a MOS transistor MT having a gate terminal G, a drain terminal D and a source terminal S, and a bipolar transistor BT having a collector terminal K, an emitter terminal E and a base terminal B. In this case, the drain terminal of the MOS transistor MT is connected to the collector terminal K of the bipolar transistor BT. The source terminal S is connected to the base terminal B of the bipolar transistor BT, the source terminal S of the MOS transistor MT being short-circuited to the body zone thereof. A resistor R is connected between the base terminal B and the emitter terminal E of the bipolar transistor BT. The short circuit between the source terminal S of the MOS transistor MT and the base terminal B of the bipolar transistor BT is realized by the source-base contact 32, with reference to FIG. 1. The resistor layer 50 between the source-base contact 32 and the emitter contact 42 in FIG. 1 forms the resistor R in accordance with FIG. 4.

If, in the case of the semiconductor component according to the invention, a drive voltage is applied between the gate electrode 80 and the source zone 30 or the source-base contact 32, then a conductive channel is formed in the body zone 20 between the source zone 30 and the drift zone 14. When a voltage is applied between the collector zone, or the drain zone 12, and the emitter zone 40, electrons flow from the heavily n-doped drain or collector zone 12 via the drift zone 14 and the conductive channel into the source zone 30. As a result, holes are injected into the base 20 via the source-base contact 32, which short-circuits the source zone 30 and the base 20. The holes drive the bipolar transistor if the hole current has reached a specific predetermined intensity.

When the bipolar transistor is driven, charge carriers are exchanged between the heavily n-doped collector zone 12 and the heavily n-doped emitter zone 40.

If the bipolar transistor is intended to turn off, then the holes present in the base 20 must recombine with free electrons, which leads to a delay time during the turn-off of the bipolar transistor. In this case, some of the holes can flow away via the resistor 50 and an emitter contact 42 which makes contact with the emitter zone, as a result of which the resistor 50 contributes to reducing the delay time which occurs during the turn-off. Holes generated in the base-collector space charge zone can be dissipated via the resistor, as a result of which the emitter-collector breakdown voltage of the bipolar transistor rises.

FIG. 5 shows a further exemplary embodiment of the semiconductor component according to the invention, wherein a breakdown structure is realized in the semiconductor body 1, the structure having a p-doped well 94 which extends into the semiconductor body 1 in the vertical direction proceeding from the front side 5 of the semiconductor body 1. The p-doped zone 94 has a contact 90, which is connected to the emitter contact 42 of the bipolar transistor in a manner not illustrated in any further detail. A second terminal of the breakdown structure is formed by the heavily n-doped terminal zone 12 or the contact layer 70. In the exemplary embodiment illustrated, this breakdown structure forms a diode which is reverse-biased between the collector 12, 70 and the emitter 40, 42 of the bipolar transistor and whose breakdown voltage is dependent on the doping of the drift zone 14 and the shortest distance between the heavily n-doped terminal zone 12 and the p-doped zone 94. The breakdown voltage at which said breakdown structure starts to conduct, or enters into breakdown, is dimensioned in such a way that it is lower than the breakdown voltage of the base-collector diode of the bipolar transistor. As a result, the breakdown voltage of the bipolar transistor is never reached, which contributes to the protection of the bipolar transistor. In bipolar transistors, a so-called snapback effect occurs when they enter into breakdown, i.e. the breakdown voltage is reduced again after the breakdown has been reached, wherein case the situation can arise wherein the breakdown voltage has different magnitudes in different regions of the base-collector diode, with the result that said diode already turns on or is still turned on in some regions, while it is still turned off in other regions. This can lead to an excessive current loading of the already conductive regions and ultimately to destruction of the transistor. This effect is prevented by the breakdown structure which breaks down before the bipolar transistor.

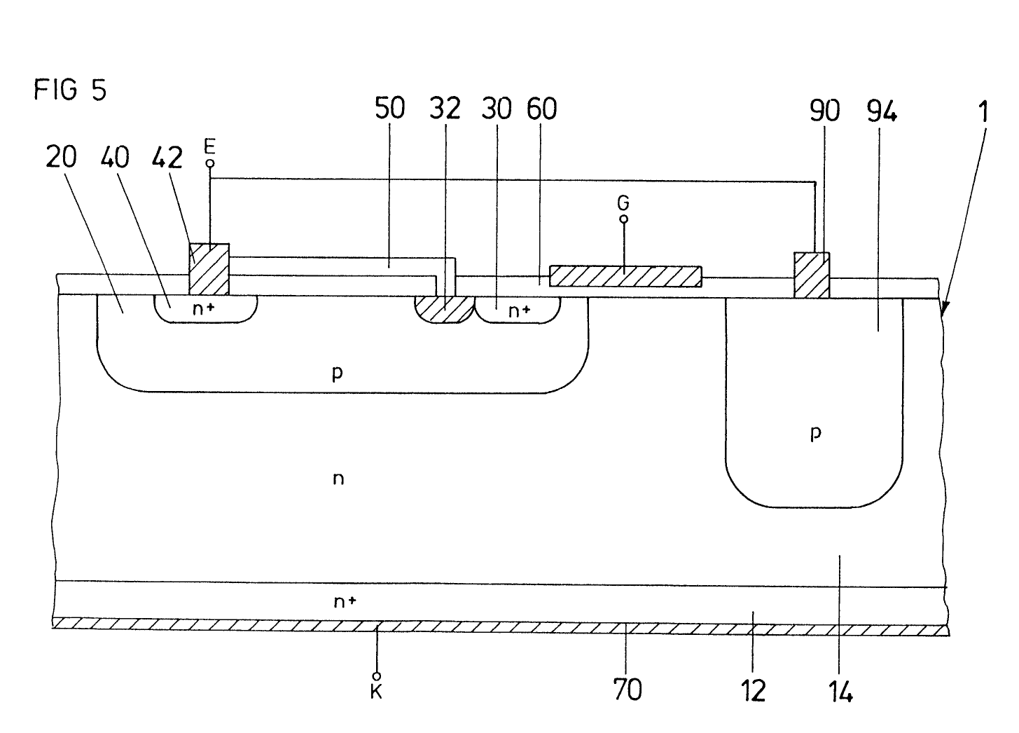

FIGS. 1 and 5 show a semiconductor component according to the invention which is formed as a vertical component, i.e. the emitter contact 40 and the collector contact 70 of the bipolar transistor are accessible at mutually opposite surfaces of the semiconductor body and charge carriers flow in the vertical direction through the semiconductor body. By contrast, FIG. 6 shows a semiconductor component according to the invention of lateral design, wherein the heavily n-doped collector or drain zone 12 is arranged in a manner spaced apart from the source and emitter zones 30, 40, and the body or base zone 20, in the lateral direction of the semiconductor body 1.

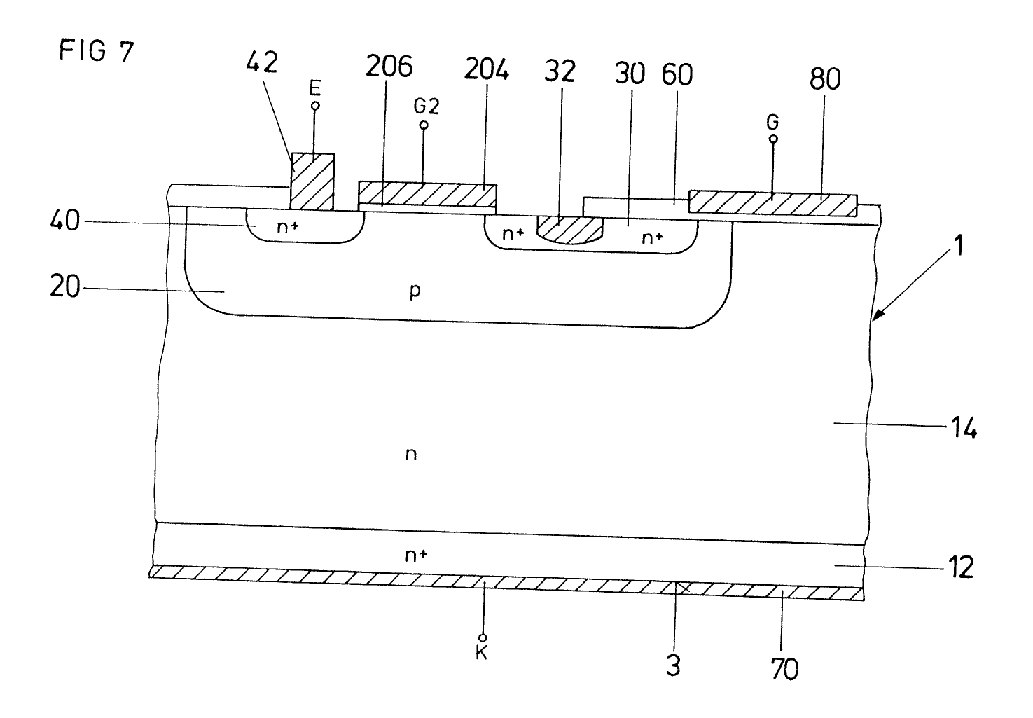

In accordance with one embodiment of the invention, provision is made for forming the resistor between the source-base contact 32 and the emitter contact 42 as a controllable resistor, in particular as a transistor. FIG. 7 shows an exemplary embodiment of such a semiconductor component in cross section.

In the exemplary embodiment of FIG. 7, a second gate electrode 204 is arranged with a gate terminal G2 opposite on the semiconductor body 1 above the body or base zone and extends in the lateral direction from the emitter zone 40 as far as the source zone 30, the source zone 30 being formed on both sides around the terminal contact 32, or surrounding the terminal contact 32. The second gate electrode 204 is insulated from the semiconductor body by means of an insulation layer. The second gate electrode 203 is part of a field-effect transistor whose body zone is formed by the body zone 20 below the second gate electrode 204 and whose source and drain zones are formed by the emitter zone 40 and the source zone 30. When a drive potential is applied to the second gate electrode 203, or the second gate terminal G2, a conductive channel forms in the body zone 20 below the second gate electrode 204 between the source zone 30 and the emitter zone 40. The conductive channel represents a resistor between the source zone 30 and the emitter zone 40, the resistance of this conductive channel being dependent on the drive potential at the second gate electrode 204.

The switching properties of the IBT can be influenced by way of the resistor, which can be controlled via the second gate electrode G2 and is realized as a MOS transistor in the exemplary embodiment. If the auxiliary MOS transistor with the second gate electrode G2, 204 is completely turned on, then the resistance between the source zone 30 and the emitter zone 40 is very small, these two zones 30, 40 are then approximately short-circuited and the IBT then functions essentially as a MOS transistor. If the auxiliary MOS transistor is driven in such a way that its on resistance, or the resistance of the channel between the source zone 30 and the emitter zone 40, is not negligible, then the semiconductor component according to the invention functions as an IBT, i.e. the bipolar transistor is driven by means of the MOS transistor, said semiconductor component advantageously combining the approximately power-free driving of a MOS transistor with a low on resistance of a bipolar transistor.

We claim:

1. A semiconductor component, comprising:
a first terminal zone of a first conductivity type and a drift zone of the first conductivity type adjoining said first terminal zone;
a second terminal zone of the first conductivity type;
a third terminal zone of the first conductivity type;
a blocking zone formed between said drift zone and said second terminal zone and between said drift zone and said third terminal zone;
a contact short-circuiting said second terminal zone and said blocking zone;
a control electrode formed to be insulated from said drift zone, said blocking zone, and said second terminal zone; and
an electrical resistor formed between said contact and said third terminal zone.

2. The semiconductor component according to claim 1, wherein said blocking zone is formed as a well in said drift zone, and wherein said second and third terminal zones are formed to be spaced apart from one another in said blocking zone.

3. The semiconductor component according to claim 1, wherein said drift zone is formed in a semiconductor body having a first surface, and said first terminal zone is formed in said first surface of said semiconductor body.

4. The semiconductor component according to claim 1, wherein said second and third terminal zones are formed in mutually opposite surfaces of a semiconductor body.

5. The semiconductor component according to claim 1 integrated in a semiconductor body and comprising a breakdown structure having first and second terminals integrated in the semiconductor body, said breakdown structure conducting when a predetermined voltage is reached between said first and second terminals.

6. The semiconductor component according to claim 5, wherein said breakdown structure has a doped zone of the second conductivity type in said drift zone.

7. The semiconductor component according to claim 5, wherein one of said first and second terminals of said breakdown structure is connected to said third terminal zone, and the other of said first and second terminals of said breakdown structure is connected to said first terminal zone.

8. The semiconductor component according to claim 1, wherein said drift zone is formed in a semiconductor body having a first surface, and said resistor is formed above said surface of the semiconductor body.

9. The semiconductor component according to claim 1, wherein said resistor is a controllable resistor.

10. The semiconductor component according to claim 1, wherein said resistor is a transistor.
